(19) United States
(12) Patent Application Publication
(10) Pub. No.: US 2023/0409902 A1
(43) Pub. Date: Dec. 21, 2023

(54) ELECTRONIC DEVICE PERFORMING SIMULATION OF TARGET ROW REFRESH LOGIC OF DYNAMIC RANDOM ACCESS MEMORY AND OPERATING METHOD OF ELECTRONIC DEVICE

(71) Applicant: SAMSUNG ELECTRONICS CO., LTD., Suwon-si (KR)

(72) Inventors: Changhwi PARK, Suwon-si (KR); Hyojin CHOI, Suwon-si (KR)

(21) Appl. No.: 18/113,794

(22) Filed: Feb. 24, 2023

(30) Foreign Application Priority Data
May 27, 2022 (KR) 10-2022-0065199
Aug. 10, 2022 (KR) 10-2022-0099986

(51) Int. Cl. G06N 3/08; G06N 3/0475

(52) U.S. Cl. CPC G06N 3/08; G06N 3/0475

(57) ABSTRACT

An operating method of an electronic device is disclosed. The operating method includes generating an input tensor by using a generator network, obtaining a first score by inputting the input tensor to a target row refresh logic module, storing a pair of the generator network and the first score in an evolution pool when the first score is greater than a threshold value, training a critic network based on the input tensor and the first score when the number of times of iteration is smaller than the maximum number of times of iteration, and training the generator network based on a training result of the critic network when the number of times of iteration is smaller than the maximum number of times of iteration.

### CROSS-REFERENCE TO RELATED APPLICATIONS

Korean Patent Application No. 10-2022-0065199 filed on May 27, 2022, in the Korean Intellectual Property Office, and entitled “A generative-evolutionary-optimization approach to evaluate row-hammering mitigation schemes,” and Korean Patent Application No. 10-2022-0099986 filed on Aug. 10, 2022, in the Korean Intellectual Property Office, and entitled “Electronic Device Performing Simulation of Target Row Refresh Logic of Dynamic Random Access Memory and Operating Method of Electronic Device” are incorporated by reference herein in their entireties.

### BACKGROUND

### 1. Field

Embodiments of the present disclosure described herein relate to an electronic device, and more particularly, relate to an electronic device including a processor performing simulation of target row refresh logic of a dynamic random access memory based on a neural network and an operating method of the electronic device.

### 2. Description of the Related Art

A dynamic random access memory may include a plurality of memory cells arranged in rows and columns. When the activation is concentrated on a specific row of the dynamic random access memory, an error may occur in data that are stored in memory cells of adjacent rows. To prevent the above issue, target row refresh logic may be applied to the dynamic random access memory.

The target row refresh logic may detect the intensive access to a specific row of the dynamic random access memory and may perform a refresh operation to recover data of memory cells of rows adjacent to the row targeted for the intensive access. As the target row refresh logic is introduced to the dynamic random access memory, a pattern of attack indicating the intensive access to rows of the dynamic random access memory may diversify.

Accordingly, the performance of the target row refresh logic may be determined based on the number of intensive row access patterns that the target row refresh logic is capable of detecting. The accuracy of simulation for evaluating the performance of the target row refresh logic may be determined based on the number of intensive row access patterns capable of being generated.

### SUMMARY

Embodiments of the present disclosure provide an electronic device simulating target row refresh logic with various access patterns during a short time and an operating method of the electronic device.

According to an embodiment, an operating method of an electronic device which includes a processor performing simulation of target row refresh logic of a dynamic random access memory includes generating an input tensor by the processor by using a generator network, obtaining a first score by the processor by inputting the input tensor to a target row refresh logic module, storing a pair of the generator network and the first score in an evolution pool by the processor when the first score is greater than a threshold value, training a critic network based on the input tensor and the first score by the processor when the number of times of iteration is smaller than the maximum number of times of iteration, training the generator network based on a training result of the critic network by the processor when the number of times of iteration is smaller than the maximum number of times of iteration, and again performing the generating of the input tensor, the obtaining of the first score, and the storing the pair of the generator network and the first score in the evolution pool by the processor when the number of times of iteration is smaller than the maximum number of times of iteration.

According to an embodiment, an electronic device includes a processor, and a memory. The processor executes a simulator performing simulation of target row refresh logic of a dynamic random access memory by using the memory. The simulator includes a first module that executes an algorithm of the target row refresh logic and to output a risk level as a first score, and a second module that performs the simulation by using the first module. The second module includes a generator pool that includes a plurality of generator networks each configured to generate an input tensor of the first module, and a critic network that is trained to replicate the first module and to infer a second score from the input tensor. Each of the plurality of generator networks is repeatedly trained together with the critic network. In each iteration where the training is repeated, when the first score is greater than a threshold value, a generator network corresponding to the first score is stored in an evolution pool together with the first score.

According to an embodiment, an operating method of an electronic device which includes a processor performing simulation of target row refresh logic of a dynamic random access memory includes storing generator networks in an evolution pool by repeatedly training each of a plurality of generator networks and a critic network, and repeatedly training each generator network of the evolution pool and the critic network. The training of each generator network and the critic network includes generating an input tensor by using each generator network, generating a first score by using a target row refresh logic module based on the input tensor, storing each generator network in the evolution pool when the first score is greater than a threshold value, generating a second score from the input tensor by using the critic network, training the critic network such that the first score is generated from the input tensor, and training the generator network such that the second score reaches the first score by the input tensor.

### BRIEF DESCRIPTION OF THE DRAWINGS

Features will become apparent to those of skill in the art by describing in detail exemplary embodiments with reference to the attached drawings in which:

FIG. 1 is a diagram illustrating a dynamic random access memory according to an embodiment of the present disclosure.

FIG. 2 is a diagram illustrating an example of an operating method of target row refresh logic of control logic of a dynamic random access memory.

FIG. 3 is a diagram illustrating an electronic device according to an embodiment of the present disclosure.

FIG. 4 is a diagram illustrating an example of an operating method of a target row refresh simulator of FIG. 3.

FIG. 5 is a diagram illustrating an example of processes performed in a target row refresh simulator based on an operating method of FIG. 4.

FIG. 6 is a diagram illustrating an example where generative evolutionary optimization simulation is performed on generator networks of an evolution pool after the generative evolutionary optimization simulation is completely performed on generator networks of a generator pull.

FIG. 7 is a diagram illustrating an example of a method in which a target row refresh simulator extends an evolution direction of generative evolutionary optimization simulation.

FIG. 8 is a diagram illustrating a result of performing a simulation on a target row refresh logic module having four types by using a target row refresh simulator according to an embodiment of the present disclosure.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey exemplary implementations to those skilled in the art.

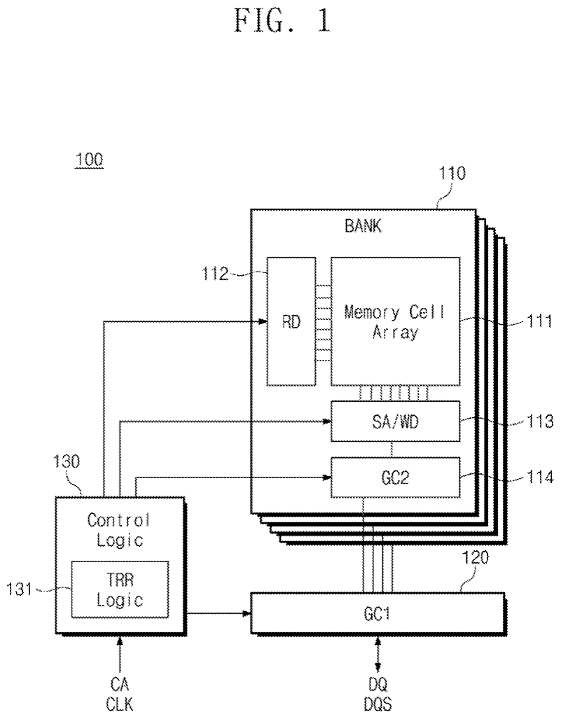

FIG. 1 is a diagram illustrating a dynamic random access memory 100 according to an embodiment of the present disclosure. Referring to FIG. 1, the dynamic random access memory 100 may include a plurality of banks (BANK) 110, a first gating circuit (GC1) 120, and control logic 130.

Each of the plurality of banks 110 may include a memory cell array 111, a row decoder (RD) 122, a sense amplifier and write driver (SA/WD) 113, and a second gating circuit (GC2) 114.

The memory cell array 111 may include memory cells arranged in rows and columns. The rows of the memory cells may be connected to word lines, and the columns of the memory cells may be connected to bit lines.

The row decoder 112 may be connected to the rows of the memory cells in the memory cell array 111 through word lines. The row decoder 112 may activate one (e.g., a word line) of the rows of the memory cells in the memory cell array 111 under control of the control logic 130, for example, in response to a row address received from the control logic 130.

The sense amplifier and write driver 113 may be connected to the columns of the memory cells in the memory cell array 111 through the bit lines. When a row of the memory cell array 111 is selected and activated, the sense amplifier and write driver 113 may read data stored in memory cells of the activated row under control of the control logic 130. When the selected row of the memory cell array 111 is deactivated, the sense amplifier and write driver 113 may write data in the memory cells of the row to be deactivated under control of the control logic 130. The sense amplifier and write driver 113 may include a plurality of sense amplifiers and a plurality of write drivers, each of which corresponds to each bit line.

The second gating circuit 114 may be connected to the plurality of sense amplifiers and the plurality of write drivers of the sense amplifier and write driver 113. Under control of the control logic 130, for example, in response to a column address transferred from the control logic 130, the second gating circuit 114 may electrically connect sense amplifiers corresponding to the column address from among the plurality of sense amplifiers with the first gating circuit 120 (e.g., in the read operation) and may electrically connect write drivers corresponding to the column address from among the plurality of write drivers with the first gating circuit 120 (e.g., in the write operation).

The first gating circuit 120 may be connected to the plurality of banks 110. Under control of the control logic 130, for example, in response to a bank address transferred from the control logic 130, the first gating circuit 120 may output, as a data signal DQ, data transferred from a bank corresponding to the bank address from among the plurality of banks 110 to an external device in synchronization with a data strobe signal DQS (e.g., in the read operation). The first gating circuit 120 may receive data as the data signal DQ from the external device in response to the data strobe signal DQS and may transfer the received data to the bank corresponding to the bank address from among the plurality of banks 110 (e.g., in the write operation).

The control logic 130 may receive a command and address CA and a clock signal CLK from the external device. The control logic 130 may control the plurality of banks 110 and the first gating circuit 120 in response to the command of the command and address CA. The control logic 130 may extract the bank address, the row address, and the column address from the address of the command and address CA. The control logic 130 may transfer the bank address to the first gating circuit 120, may transfer the row address to the row decoder 112, and may transfer the column address to the second gating circuit 114.

The control logic 130 may generate an internal clock signal or signals for controlling internal operation timings from the clock signal CLK. The control logic 130 may control the plurality of banks 110 and the first gating circuit 120 in synchronization with the internal clock signal or signals. The control logic 130 may generate the data strobe signal DQS to be output to the external device from the clock signal CLK.

The control logic 130 may receive various control signals from the external device and may output various control signals to the external device. In one embodiment, the plurality of banks 110 may be classified into a plurality of bank groups, and a gating circuit (e.g., a third gating circuit) for selecting the plurality of bank groups may be added. The control logic 130 may further extract a bank group address for selecting a bank group through the third gating circuit from the address of the command and address CA.

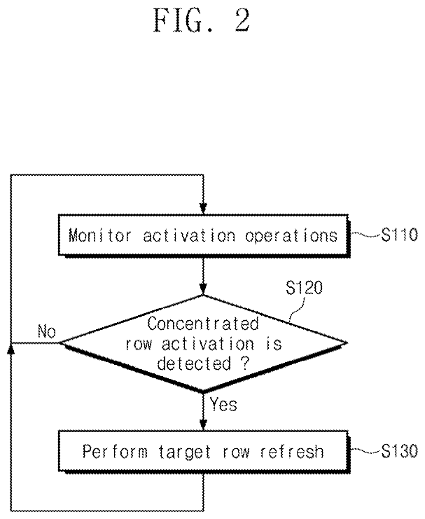

The control logic 130 may include target row refresh (TRR) logic 131 for performing a target row refresh (TRR) operation. FIG. 2 is a diagram illustrating an example of an operating method of the target row refresh logic 131 of the control logic 130 of the dynamic random access memory 100.

Referring to FIGS. 1 and 2, in operation S110, the target row refresh logic 131 may monitor activation operations. In operation S120, the target row refresh logic 131 may determine whether concentrated row activation is detected. When the concentrated row activation is not detected, the target row refresh logic 131 may perform operation S110 to again monitor the activation operations. When the concentrated row activation is detected, the target row refresh logic 131 may perform the target row refresh operation, in operation S130. For example, the target row refresh logic 131 may notify the control logic 130 (e.g., the TRR logic 131 of the control logic 130) that the concentrated row activation is detected, and the control logic 130 (e.g., the refresh logic of the control logic 130) may perform the refresh operation for recovering data with respect to rows adjacent to a row where the concentrated activation is made.

As the target row refresh logic 131 is included in the dynamic random access memory 100, there are being developed various attack patterns that intensively activate the specific row while hiding the intention to intensively activate the specific row (i.e., while avoiding the event that the concentrated activation of the specific row is detected by the target row refresh logic 131). As the number of various attack patterns capable of being detected increases, the performance of the target row refresh logic 131 may be further improved.

To further improve the performance of the target row refresh logic 131, a simulation for evaluating how variously the target row refresh logic 131 is able to detect attack patterns is required. However, there is a limitation in performing the simulation based on a result of predicting various attack patterns. The present disclosure provides an electronic device that performs a simulation of target row refresh logic by using 10,000 or more dimensions (e.g., attack patterns) based on generative evolutionary optimization and an operating method of the electronic device.

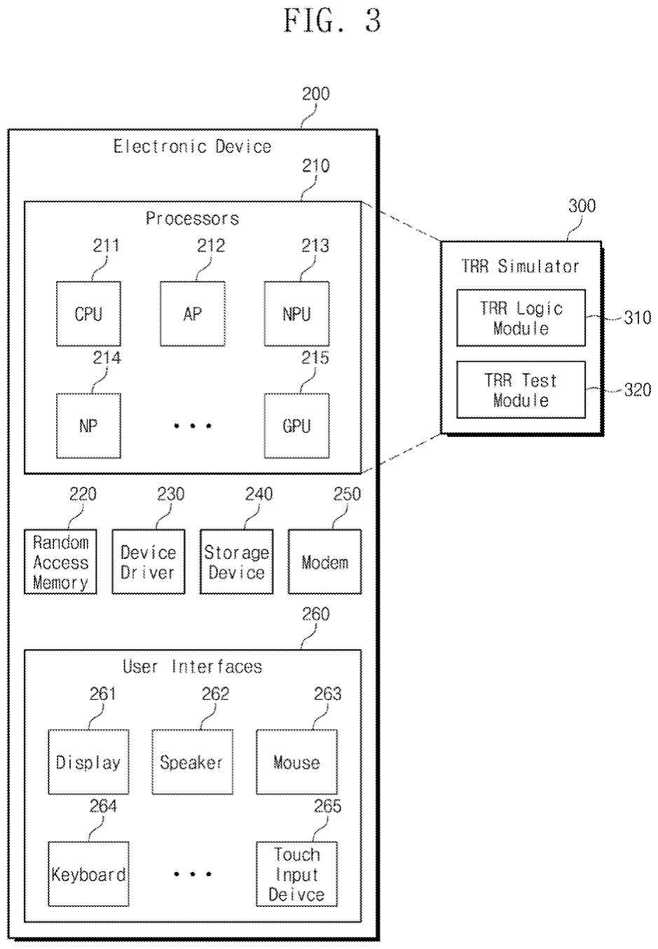

FIG. 3 illustrates an electronic device 200 according to an embodiment of the present disclosure. Referring to FIG. 3, the electronic device 200 may include processors 210, a random access memory 220, a device driver 230, a storage device 240, a modem 250, and user interfaces 260.

The processors 210 may include, for example, at least one general-purpose processor such as a central processing unit (CPU) 211 or an application processor (AP) 112. Also, the processors 210 may further include at least one special-purpose processor such as a neural processing unit (NPU) 213, a neuromorphic processor (NP) 214, or a graphics processing unit (GPU) 215. The processors 210 may include two or more homogeneous processors.

At least one of the processors 210 may execute a target row refresh simulator 300. For example, the target row refresh simulator 300 may be implemented in the form of instructions (or codes) that are executed by at least one of the processors 210. In this case, the at least one processor may load the instructions (or codes) of the target row refresh simulator 300 into the random access memory 220.

As another example, at least one (or at least another) processor of the processors 210 may be fabricated to implement the target row refresh simulator 300. For example, at least one processor may be a dedicated processor that implements functions of the target row refresh simulator 300 in hardware.

The random access memory 220 may be used as a working memory of the processors 210 and may be used as a main memory or a system memory of the electronic device 200. The random access memory 220 may include a volatile memory such as the dynamic random access memory 100 or a static random access memory. The random access memory 220 may also include a nonvolatile memory such as a phase-change random access memory, a ferroelectric random access memory, a magnetic random access memory, or a resistive random access memory.

The random access memory 220 may store data that are necessary for the simulation of the target row refresh simulator 300. For example, the random access memory 220 may receive data from the storage device 240 or may receive data from an external device (e.g., a database) through the modem 250.

The device driver 230 may control the following peripheral devices depending on a request of the processors 210: the storage device 240, the modem 250, and the user interfaces 260. The storage device 240 may include a stationary storage device such as a hard disk drive or a solid-state drive, or a removable storage device such as an external hard disk drive, an external solid-state drive, or a removable memory card.

The storage device 240 may store data that are necessary for the simulation of the target row refresh simulator 300. The data stored in the storage device 240 may be loaded to the random access memory 220 and may be used for the simulation of the target row refresh simulator 300.

The modem 250 may provide remote communication with the external device. The modem 250 may perform wired or wireless communication with the external device. The modem 250 may communicate with the external device based on at least one of various communication schemes such as Ethernet, wireless-fidelity (Wi-Fi), long term evolution (LTE), and 5G mobile communication. The modem 250 may receive data, which are necessary for the simulation of the target row refresh simulator 300, from the external device, for example, the database. The modem 250 may load the received data to the random access memory 220.

The user interfaces 260 may receive information from the user and may provide information to the user. The user interfaces 260 may include at least one user output interface such as a display 261 or a speaker 262, and at least one user input interface such as a mouse 263, a keyboard 264, or a touch input device 265.

The target row refresh simulator 300 may measure the performance of the target row refresh logic 131 included in the control logic 130 of the dynamic random access memory 100 of FIG. 1 through the simulation. The target row refresh simulator 300 may be implemented by software executable by one of the processors 210, hardware composed of one of the processors 210, or a combination thereof.

The target row refresh simulator 300 may include a target row refresh logic module 310 and a target row refresh test module 320. The target row refresh logic module 310 may be configured to execute the algorithm of the target row refresh logic 131 included in the control logic 130 of the dynamic random access memory 100 of FIG. 1. The target row refresh logic module 310 may monitor the activation operations in the same manner as the target row refresh logic 131 and may detect the concentrated activation of the specific row. The target row refresh logic module 310 may generate a score of the degree to which data are lost by the concentrated activation, for example, a score of a risk level.

The target row refresh test module 320 may perform the simulation of the target row refresh logic 131 by using the target row refresh logic module 310. For example, the target row refresh test module 320 may perform the simulation of the target row refresh logic 131 by using the generative evolutionary optimization.

In the simulation process, the target row refresh test module 320 may provide an input to the target row refresh logic module 310 and may receive the score of the risk level from the target row refresh logic module 310. The target row refresh test module 320 may perform the simulation without using any other information (e.g., internal status information and middle information) of the target row refresh test module 320, except for the input to the target row refresh logic module 310 and the score output from the target row refresh logic module 310. That is, the target row refresh test module 320 may perform the simulation in a state of handling the target row refresh logic module 310 as a black box. Accordingly, a limitation on a search space of the simulation (e.g., a search space of an input of the target row refresh logic module 310) may be expanded and may be substantially removed.

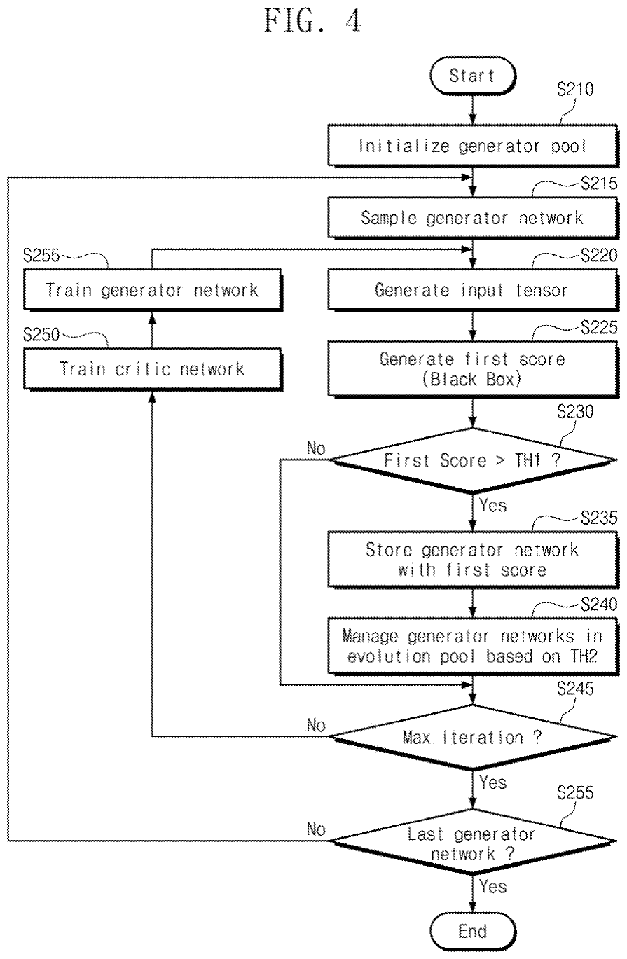

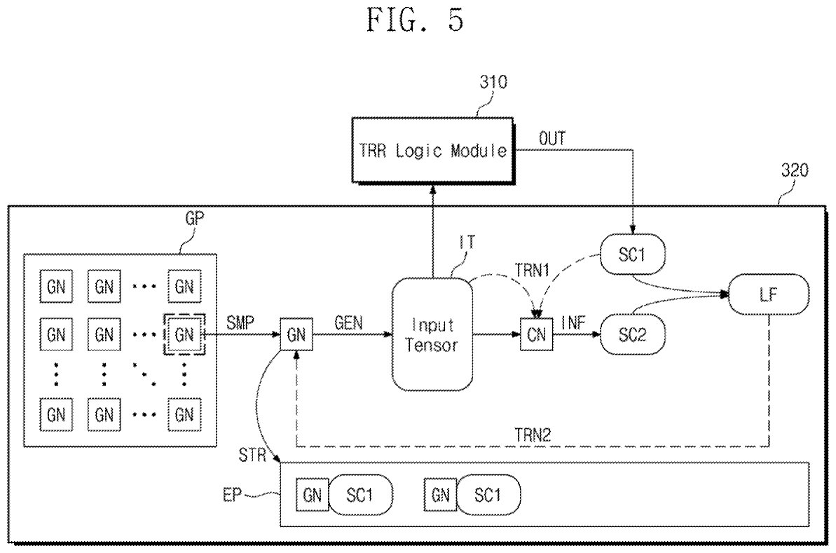

FIG. 4 is a diagram illustrating an example of an operating method of the target row refresh simulator 300 of FIG. 3. FIG. 5 is a diagram illustrating an example of processes performed in the target row refresh simulator 300 based on an operating method of FIG. 4.

Referring to FIGS. 3, 4, and 5, in operation S210, the target row refresh test module 320 may initialize a generator pool GP including a plurality of generator networks GN. For example, the plurality of generator networks GN may have the same structures (or algorithms). The target row refresh test module 320 may initialize the plurality of generator networks GN by setting internal parameters of the plurality of generator networks GN in a different manner.

In an embodiment, each of the plurality of generator networks GN may be configured to generate an input of the target row refresh logic module 310, for example, an input tensor including various patterns of row addresses targeted for activation. As the internal parameters of the plurality of generator networks GN are differently set, input tensors that the plurality of generator networks GN generate, that is, various patterns of row addresses targeted for activation may be different from each other.

In operation S215, the target row refresh test module 320 may sample one of the plurality of generator networks GN of the generator pool GP (refer to “SMP” in FIG. 5).

In operation S220, the target row refresh test module 320 may generate an input tensor IT by using the sampled generator network GN (refer to “GEN” in FIG. 5). For example, the generator network GN may generate the input tensor IT by using a random number (or a random noise) or a pseudo random number (or a pseudo random noise) as a seed. The input tensor IT may include various patterns of row addresses targeted for activation.

In operation S225, the target row refresh simulator 300 may generate a first score SC1. For example, the target row refresh test module 320 may transfer the input tensor IT to the target row refresh logic module 310. The target row refresh logic module 310 may detect whether a row address of a specific row is intensively generated, from the patterns of the row addresses of the input tensor IT. When it is determined that a row address of a specific row is not intensively generated, the target row refresh logic module 310 may increase the risk level. Whether a row address is intensively generated may be detected with respect to all the patterns of the input tensor IT; when a level obtained by accumulating detection results reaches the risk level, the target row refresh logic module 310 may output the risk level corresponding to the accumulated detection results as the first score SC1. The first score SC1 may be transferred to the target row refresh test module 320.

The target row refresh logic module 310 may be handled as a black box in the target row refresh simulator 300 in that any other information of the target row refresh logic module 310 is not transferred to the target row refresh test module 320 except for the first score SC1.

In operation S230, the target row refresh test module 320 may determine whether a value of the first score SC1 is greater than a first threshold value TH1. When a value of the first score SC1 is greater than the first threshold value TH1, in operation S235, the target row refresh test module 320 may store the generator network GN in an evolution pool EP together with the first score SC1 (refer to “STR” in FIG. 5). Afterwards, in operation S240, the target row refresh test module 320 may manage the generator networks GN in the evolution pool EP based on a second threshold value TH2. For example, the target row refresh test module 320 may sort pairs of generator network GN and first score SC1 in the evolution pool EP based on values of the first scores SC1 (e.g., in the descending order from highest to lowest values). When the number of pairs of generator network GN and first score SC1 in the evolution pool EP reaches the second threshold value TH2, the target row refresh test module 320 may remove a generator network-first score (GN-SC1) pair including the first score SC1 with the smallest value from the evolution pool EP such that the number of pairs of generator network GN and first score SC1 in the evolution pool EP is maintained below the second threshold value TH2. Afterwards, the target row refresh test module 320 may perform operation S245.

When it is determined in operation S230 that the value of the first score SC1 is not greater than the first threshold value TH1, that is, when the value of the first score SC1 is smaller than or equal to the first threshold value TH1, the target row refresh test module 320 may not perform (or may skip) operation S235 and operation S240 and may directly perform operation S245.

In operation S245, the target row refresh test module 320 may determine whether the generative evolutionary optimization simulation is performed on the sampled generator network GN as much as the number of times of max iteration. When the number of times of iteration is smaller than the number of times of max iteration, in operation S250, the target row refresh test module 320 may train (or may perform learning on) a critic network CN (refer to “TRN1” in FIG. 5). For example, the target row refresh test module 320 may train the critic network CN based on the input tensor IT and the first score SC1 (refer to “TRN1” in FIG. 5). The target row refresh test module 320 may train the critic network CN such that the critic network CN generates the first score SC1 from the input tensor IT (refer to “TRN1” in FIG. 5). That is, the critic network CN may be trained by a surrogate network of the target row refresh logic module 310 (refer to “TRN1” in FIG. 5).

In operation S255, the target row refresh test module 320 may train (or may perform learning on) the generator network GN (refer to “TRN2” in FIG. 5). For example, the target row refresh test module 320 may infer a second score SC2 from the input tensor IT by using the trained critic network CN. The target row refresh test module 320 may calculate a loss function LF from the first score SC1 and the second score SC2. For example, the target row refresh test module 320 may calculate a difference between the first score SC1 and the second score SC2 as the loss function LF.

The target row refresh test module 320 may train the generator network GN by using the loss function LF (refer to “TRN2” in FIG. 5). For example, the target row refresh test module 320 may train the generator network GN such that the loss function LF decreases, that is, such that the second score SC2 is closer to (or reaches) the first score SC1. The target row refresh test module 320 may train the generator network GN such that the input tensor IT is generated that allows the second score SC2 to be closer to the first score SC1.

When it is determined in operation S245 that the number of times of iteration of the generative evolutionary optimization simulation is not smaller than the number of times of max iteration, that is, when the number of times of iteration reaches the number of times of max iteration, the target row refresh test module 320 may terminate the iteration of the generative evolutionary optimization simulation of the sampled generator network GN and may perform operation S255.

Operation S210 to operation S245 may correspond to the generative evolutionary optimization simulation of one generator network GN. The first iteration of the generative evolutionary optimization simulation may include generating the input tensor IT by using the initialized generator network GN (S220), generating the first score SC1 from the input tensor IT by using the target row refresh logic module 310 (S225), and storing a generator network-first score (GN-SC1) pair including the first score SC1 greater in value than the first threshold value TH1 in the evolution pool EP (S230, S235, and S240).

The iteration(s) following the first iteration of the generative evolutionary optimization simulation may include training the critic network CN by using the input tensor IT and the first score SC1 of the previous iteration (S250), training the generator network GN based on the loss function LF corresponding to a difference between the first score SC1 and the second score SC2, which is inferred from the input tensor IT by using the trained critic network CN (S255), generating the input tensor IT by using the trained generator network GN (S220), generating the first score SC1 from the input tensor IT by using the target row refresh logic module 310 (S225), and storing a generator network-first score (GN-SC1) pair including the first score SC1 greater in value than the first threshold value TH1 in the evolution pool EP (S230, S235, and S240).

In one embodiment, to collect initial data for training the sampled generator network GN, the first iteration described above may be performed as much as M times (M being a positive integer), and the input tensors IT, the first scores SC1, and the second scores SC2 may be collected. Afterwards, after the first iteration is performed as much as M times, the iterations following the first iteration may be performed.

In operation S255, the target row refresh test module 320 may determine whether a generator network experiencing the generative evolutionary optimization simulation is the last generator network. For example, the target row refresh test module 320 may determine whether the generative evolutionary optimization simulation is performed on all the generator networks GN in the generator pool GP. When the generator network experiencing the generative evolutionary optimization simulation is not the last generator network, in operation S215, the target row refresh test module 320 may sample a generator network GN, on which the generative evolutionary optimization simulation is not yet performed, from among the generator networks GN in the generator pool GP. Afterwards, in operation S220 to operation S245, the target row refresh simulator 300 may perform the generative evolutionary optimization simulation of the sampled generator network GN.

When it is determined in operation S255 that the generator network experiencing the generative evolutionary optimization simulation is the last generator network, that is, when it is determined that the generative evolutionary optimization simulation is performed on all the generator networks GN in the generator pool GP, the target row refresh simulator 300 may terminate the simulation for the target row refresh logic 131.

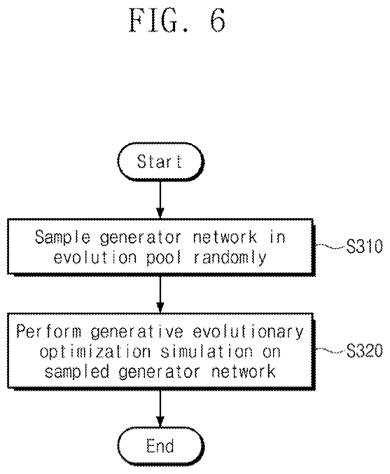

FIG. 6 is a diagram illustrating an example in which the generative evolutionary optimization simulation is performed on the generator networks GN of the evolution pool EP after the generative evolutionary optimization simulation is completely performed on the generator networks GN of the generator pool GP. Referring to FIGS. 3, 5, and 6, in operation S310, the target row refresh logic module 310 may randomly select one of the generator networks GN of the evolution pool EP. In one embodiment, the target row refresh test module 320 may randomly select one of generator networks GN, the number of which corresponds to the second threshold value TH2 of the evolution pool EP.

In operation S320, the target row refresh simulator 300 may perform the generative evolutionary optimization simulation on the sampled generator network GN. The generative evolutionary optimization simulation for the sampled generator network GN may be similar to the generative evolutionary optimization simulation of FIG. 4.

In one embodiment, the first iteration of the generative evolutionary optimization simulation for the sampled generator network GN may include generating the input tensor IT by using the sampled generator network GN (S220 of FIG. 4), generating the first score SC1 from the input tensor IT by using the target row refresh logic module 310 (of S225 of FIG. 4), and storing a generator network-first score (GN-SC1) pair including the first score SC1 greater in value than the first threshold value TH1 in the evolution pool EP (S230, S235, and S240 of FIG. 4).

The iteration(s) following the first iteration of the generative evolutionary optimization simulation may include training the critic network CN by using the input tensor IT and the first score SC1 of the previous iteration (S250 of FIG. 4), training the generator network GN based on the loss function LF corresponding to a difference between the first score SC1 and the second score SC2, which is inferred from the input tensor IT by using the trained critic network CN (S255 of FIG. 4), generating the input tensor IT by using the trained generator network GN (S220 of FIG. 4), generating the first score SC1 from the input tensor IT by using the target row refresh logic module 310 (S225 of FIG. 4), and storing a generator network-first score (GN-SC1) pair including the first score SC1 greater in value than the first threshold value TH1 in the evolution pool EP (S230, S235, and S240 of FIG. 4).

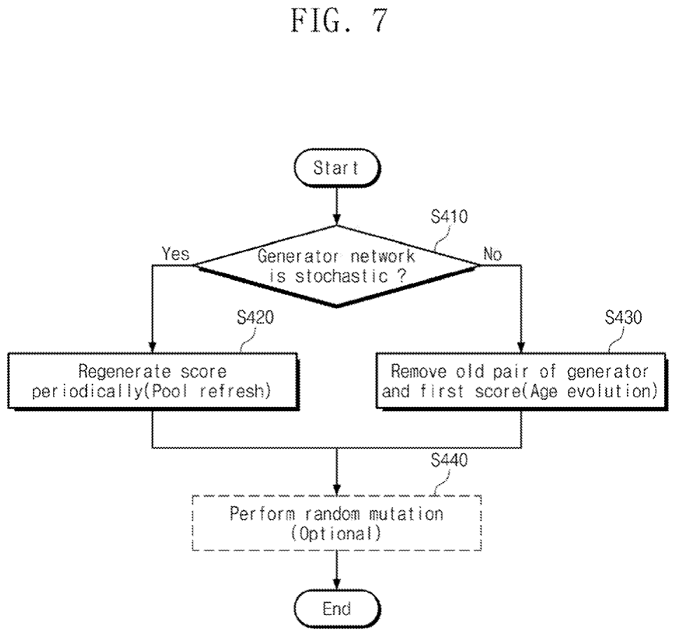

FIG. 7 is a diagram illustrating an example of a method in which the target row refresh simulator 300 extends an evolution direction of the generative evolutionary optimization simulation. Referring to FIGS. 3, 5, and 7, in operation S410, the target row refresh simulator 300 may extend the evolution direction of the generator network GN differently, depending on whether the generator network GN is stochastic or non-stochastic.

In one embodiment, when the generator network GN of the evolution pool EP uses a random number or a random noise as a seed, the generator network GN may be stochastic. When the generator network GN of the evolution pool EP is stochastic, in operation S420, the target row refresh simulator 300 may periodically regenerate a score of the generator network GN. That is, the target row refresh simulator 300 may perform a pool refresh operation on the evolution pool EP. For example, the pool refresh operation may be performed based on a period of the number of times of iteration of the generative evolutionary optimization simulation of an arbitrary generator network GN in the evolution pool EP or a period of the generative evolutionary optimization simulation of an arbitrary number of the generator networks GN of the evolution pool EP. In one embodiment, the stochastic generator networks GN of the evolution pool EP may be refreshed at the same period, at the same period but different timings, or at different periods.

When the generator network GN of the evolution pool EP uses a pseudo random number or a pseudo random noise as a seed, the generator network GN may be non-stochastic. When the generator network GN of the evolution pool EP is non-stochastic, in operation S430, the target row refresh simulator 300 may remove a generator network-first score (GN-SC1) pair being aged (e.g., the oldest) from among generator network-first score (GN-SC1) pairs of the evolution pool EP. That is, the target row refresh simulator 300 may perform age revolution of the evolution pool EP.

In operation S440, optionally, the target row refresh simulator 300 may perform a random mutation. For example, the target row refresh simulator 300 may perform random mutation periodically regardless of whether the generator networks GN of the evolution pool EP are stochastic or non-stochastic. In one embodiment, the random mutation may include training the generator network GN by using a random number or a pseudo random constant as the loss function LF.

For example, the random mutation may be performed based on a period of the number of times of iteration of the generative evolutionary optimization simulation of an arbitrary generator network GN in the evolution pool EP or a period of the generative evolutionary optimization simulation of an arbitrary number of the generator networks GN of the evolution pool EP. In one embodiment, the generator networks GN of the evolution pool EP may be randomly mutated at the same period, at the same period but different timings, or at different periods.

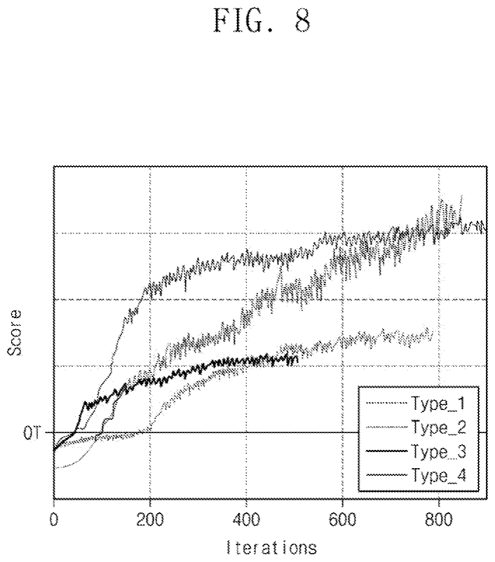

FIG. 8 is a diagram illustrating a result of performing a simulation on the target row refresh logic module 310 having four types by using the target row refresh simulator 300 according to an embodiment of the present disclosure. In FIG. 8, a horizontal axis represents the number of times of iteration of the generative evolutionary optimization simulation, and a vertical axis represents a score (e.g., the first score SC1 described above).

The target row refresh logic module 310 may have the same structure regardless of a type but may have different internal parameters for respective types Type_1, Type_2, Type_3, and Type_4. A target threshold OT may be a target score of the target row refresh simulator 300. As illustrated in FIG. 8, when at least 200 iterations are performed, the target threshold OT of the target row refresh logic module 310 may be achieved in all the types Type_1, Type_2, Type_3, and Type_4.

According to one embodiment of the present disclosure, by using the target row refresh simulator 300, the search space for simulation of the target row refresh logic module 310 may be expanded, and the performance and features of the target row refresh logic module 310 may be quickly evaluated.

In one embodiment, the target row refresh simulator 300 according to one embodiment of the present disclosure may not have a boundary condition of the search space. That is, there is no limitation on the input tensor IT for the simulation of the target row refresh logic module 310. Accordingly, the simulation may be variously performed in a wider search space.

As another embodiment, to accelerate the simulation or to avoid an error due to a structural characteristic of the target row refresh logic module 310, a boundary condition may be added to the search space of the target row refresh logic module 310. That is, the target row refresh simulator 300 according to one embodiment of the present disclosure may not have a limitation associated with the boundary condition.

In one embodiment, values that are used in the target row refresh simulator 300 may be normalized. For example, to improve the performance of the target row refresh simulator 300, values that are used in the target row refresh simulator 300 may be normalized to have a mean of “0” and to have a standard deviation of “1”.

In the above embodiments, components according to the present disclosure are described by using the terms “first”, “second”, “third”, etc. However, the terms “first”, “second”, “third”, etc. may be used to distinguish components from each other and do not limit the present disclosure. For example, the terms “first”, “second”, “third”, etc. do not involve an order or a numerical meaning of any form.

In the above embodiments, components according to embodiments of the present disclosure are referenced by using blocks. The blocks may be implemented with various hardware devices, such as an integrated circuit, an application specific IC (ASIC), a field programmable gate array (FPGA), and a complex programmable logic device (CPLD), firmware driven in hardware devices, software such as an application, or a combination of a hardware device and software. Also, the blocks may include circuits implemented with semiconductor elements in an integrated circuit, or circuits enrolled as an intellectual property (IP).

According to the present disclosure, target row refresh logic is simulated based on generative evolutionary optimization. Accordingly, an electronic device simulating the target row refresh logic with various access patterns during a short time and an operating method of the electronic device are provided.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An operating method of an electronic device which includes a processor performing simulation of target row refresh logic of a dynamic random access memory, the method comprising:
generating an input tensor by the processor by using a generator network;
obtaining a first score by the processor by inputting the input tensor to a target row refresh logic module;
storing a pair of the generator network and the first score in an evolution pool by the processor when the first score is greater than a threshold value;
training a critic network based on the input tensor and the first score by the processor when the number of times of iteration is smaller than the maximum number of times of iteration;
training the generator network based on a training result of the critic network by the processor when the number of times of iteration is smaller than the maximum number of times of iteration; and
again performing the generating of the input tensor, the obtaining of the first score, and the storing the pair of the generator network and the first score in the evolution pool by the processor when the number of times of iteration is smaller than the maximum number of times of iteration.

2. The method as claimed in claim 1, wherein the training of the critic network, the training of the generator network, the generating of the input tensor, the obtaining of the first score, and the storing the pair of the generator network and the first score in the evolution pool are iteratively performed until the number of times of iteration reaches the maximum number of times of iteration.

3. The method as claimed in claim 1, further comprising:
initializing a generator pool including a plurality of generator networks,
wherein the generating of the input tensor, the obtaining of the first score, the storing the pair of the generator network and the first score in the evolution pool, the training of the critic network, and the training of the generator network are performed on each of the plurality of generator networks.

4. The method as claimed in claim 1, wherein the training of the critic network includes:
training the critic network such that the first score is generated from the input tensor.

5. The method as claimed in claim 1, wherein the training of the generator network includes:
inferring a second score from the input tensor by using the critic network; and
training the generator network by using a difference between the first score and the second score as a loss function.

6. The method as claimed in claim 1, further comprising:
sorting generator network-first score pairs of the evolution pool based on the first score; and
when the number of the generator network-first score pairs of the evolution pool reaches a second threshold value, removing a generator network-first score pair including the first score having the smallest value from among the generator network-first score pairs of the evolution pool from the evolution pool such that the number of the generator network-first score pairs of the evolution pool is maintained below the second threshold value.

7. The method as claimed in claim 6, further comprising:
selecting one of generator networks of the evolution pool;
generating a second input tensor by using the selected generator network;
obtaining a third score by inputting the second input tensor to the target row refresh logic module;
when the third score is greater than a threshold value, storing a pair of the selected generator network and the third score in the evolution pool;
when the second number of times of iteration is smaller than the second maximum number of times of iteration, training the critic network based on the second input tensor and the third score;
when the second number of times of iteration is smaller than the second maximum number of times of iteration, training the selected generator network based on a training result of the critic network;
when the second number of times of iteration is smaller than the second maximum number of times of iteration, again performing the generating of the second input tensor, the obtaining of the third score, and the storing the pair of the selected generator network and the third score in the evolution pool.

8. The method as claimed in claim 7, further comprising:
periodically regenerating the third score of a generator network being stochastic from among the generator networks of the evolution pool.

9. The method as claimed in claim 7, further comprising:
removing an oldest generator network from among non-stochastic generator networks among the generator networks of the evolution pool from the evolution pool.

10. The method as claimed in claim 7, further comprising:
training the selected generator network based on a random number.

11. The method as claimed in claim 1, wherein the input tensor does not have a boundary condition.

12. An electronic device comprising:
a processor; and
a memory,
wherein the processor is configured to execute a simulator performing simulation of target row refresh logic of a dynamic random access memory by using the memory,
wherein the simulator includes:
a first module configured to execute an algorithm of the target row refresh logic and to output a risk level as a first score; and
a second module configured to perform the simulation by using the first module,
wherein the second module includes:
a generator pool including a plurality of generator networks each configured to generate an input tensor of the first module; and
a critic network configured to be trained to replicate the first module and to infer a second score from the input tensor,
wherein each of the plurality of generator networks is repeatedly trained together with the critic network, and
wherein, in each iteration where the training is repeated, when the first score is greater than a threshold value, a generator network corresponding to the first score is stored in an evolution pool together with the first score.

13. The electronic device as claimed in claim 12, wherein, when the number of generator network-first score pairs of the evolution pool reaches a second threshold value, a generator network-first score pair including a selected one of the first scores having the smallest value from among the generator network-first score pairs of the evolution pool is removed from the evolution pool such that the number of the generator network-first score pairs of the evolution pool is maintained below the second threshold value.

14. The electronic device as claimed in claim 12, wherein, after each of the plurality of generator networks is trained with the critic network as much as the given number of times, the training of the plurality of generator networks ends.

15. The electronic device as claimed in claim 14, wherein, after the training of the plurality of generator networks ends, each of generator networks of the evolution pool is repeatedly trained together with the critic network.

16. The electronic device as claimed in claim 15, wherein the first score of a stochastic generator network among the generator networks of the evolution pool is periodically regenerated.

17. The electronic device as claimed in claim 15, wherein a generator network being the oldest from among non-stochastic generator networks among the generator networks of the evolution pool is removed from the evolution pool.

18. The electronic device as claimed in claim 12, wherein the critic network is trained to generate the first score from the input tensor.

19. The electronic device as claimed in claim 12, wherein the generator network is trained such that the input tensor allowing the second score to be close to the first score is generated.

20. An operating method of an electronic device which includes a processor performing simulation of target row refresh logic of a dynamic random access memory, the method comprising:
storing generator networks in an evolution pool by repeatedly training each of a plurality of generator networks and a critic network; and
repeatedly training each generator network of the evolution pool and the critic network,
wherein the training of each generator network and the critic network includes:
generating an input tensor by using each generator network;
generating a first score by using a target row refresh logic module based on the input tensor;
storing each generator network in the evolution pool when the first score is greater than a threshold value;
generating a second score from the input tensor by using the critic network;
training the critic network such that the first score is generated from the input tensor; and
training each generator network such that the second score reaches the first score by the input tensor.
